(19) United States
(12) Patent Application Publication
(10) Pub. No.: US 2004/0245596 A1
(43) Pub. Date: Dec. 9, 2004

(54) Semiconductor device having trench isolation

(75) Inventor: Tsuyoshi Sugihara, Hyogo (JP)

Correspondence Address: McDermott, Will & Emery, 600 13th Street, N.W., Washington, DC, 20005-3096, US

(73) Assignee: Renesas Technology Corp.

(21) Appl. No.: 10/786,081

(22) Filed: Feb. 26, 2004

(30) Foreign Application Priority Data
Jun. 6, 2003 (JP) 2003-162602(P)

(51) Int. Cl. H01L 21/335

(52) U.S. Cl. 257/499

(57) ABSTRACT

A semiconductor device having a trench isolation includes a trench formed in a surface of a semiconductor substrate and a buried insulating layer which fills the inside of the trench and has its top surface entirely located above the surface of the semiconductor substrate. A part of the buried insulating layer that protrudes from the surface of the semiconductor substrate has a projecting portion which is located on the surface of the semiconductor substrate and projects outward from a region directly above the trench. The projecting portion has a structure formed of at least two stacked insulating layers. Accordingly, the semiconductor device having the trench isolation can be provided by which a reverse narrow-channel effect can be suppressed and a reliable gate insulating layer can be obtained.

### BACKGROUND OF THE INVENTION

1. Field of the Invention

The present invention relates to a semiconductor device having a trench isolation. More specifically, the present invention relates to a semiconductor device having a trench isolation for electrically isolating a semiconductor element from other semiconductor elements.

2. Description of the Background Art

In recent years, as patterns for semiconductor devices have increased in density, a structure called shallow trench isolation (STI) has commonly been employed as an element isolation structure for electrically isolating such a semiconductor element as field-effect transistor from other semiconductor elements. This STI is disclosed for example in Japanese Patent Laying-Open Nos. 2002-100671, 2002-93900 and 11-67892.

An STI is fabricated for example through the following process.

On a semiconductor substrate, a thermal oxide film and a silicon nitride film are formed and a resist pattern is formed on the silicon nitride film. The resist pattern is used as a mask to anisotropically etch the silicon nitride film and the thermal oxide film and thereby transfer the resist pattern to the silicon nitride film and the thermal oxide film. The resist pattern is thereafter removed.

The silicon nitride film is then used as a mask to anisotropically etch the semiconductor substrate and thereby make a trench in the surface of the semiconductor substrate. Subsequently, thermal oxidation is performed to form a thermal oxide film on the inner surface of the trench. An oxide film is formed to fill the inside of the trench and to cover the silicon nitride film. The oxide film is polished away by CMP (Chemical Mechanical Polishing) to expose the upper surface of the silicon nitride film. The silicon nitride film and the thermal oxide film are thereafter removed. In this way, an STI is completed having the trench in the surface of the semiconductor substrate that is filled with the oxide film.

The recent increase in density of the pattern is accompanied by a decrease in width of an active layer. Therefore, influences of the reverse narrow-channel effect on transistors have become issues which are not negligible. In addition, for flash memories, a reliable gate insulating layer has become necessary since electrons pass through the gate insulating layer of the flash memories.

The above-described method of forming the STI, however, somewhat etches away the oxide film which fills the trench, in the step of etching away the thermal oxide film. As a result, a depression is generated between the oxide film and the sidewall of the trench” On this depression, a gate insulating layer is formed and a gate electrode is formed on the gate insulating layer. Then, the issues of the reverse narrow-channel effect and deterioration in reliability of the gate insulating layer are encountered to make it difficult to manufacture high-performance transistors and flash memories.

### SUMMARY OF THE INVENTION

An object of the present invention is to provide a semiconductor device having a trench isolation which can suppress the reverse narrow-channel effect and make a gate insulating layer reliable.

A semiconductor device having a trench isolation is, according to the present invention, a semiconductor device having a trench isolation for electrically isolating a semiconductor element from other semiconductor elements, and the semiconductor device includes a semiconductor substrate and a buried insulating layer. The semiconductor substrate has a trench for the trench isolation in a main surface of the semiconductor substrate. The buried insulating layer fills the inside of the trench and has its top surface entirely located above the main surface of the semiconductor substrate. A part of the buried insulating layer that protrudes from the main surface of the semiconductor substrate has a projecting portion which is located on the main surface of the semiconductor substrate and projects outward from a region directly above the trench. The projecting portion has a structure formed of at least two stacked insulating layers.

The semiconductor device having the trench isolation according to the present invention has the buried insulating layer which includes the projecting portion located on the main surface of the semiconductor substrate and projects outward from the region directly above the trench. Therefore, a depression of the buried insulating layer between the buried insulating layer and the sidewall of the trench can be prevented from appearing. Accordingly, the reverse narrow-channel effect and the deterioration in reliability of the gate insulating layer due to the depression can be prevented.

Further, as the projecting portion has the structure formed of at least two stacked insulating layers, the two layers may be of different materials respectively or the same material. The two layers may be of different materials respectively in such a manner that the material of the upper insulating layer is hard to remove in the step of removing the lower insulating layer. In this case, in the step of removing the lower insulating layer, it hardly occurs that a depression of the buried insulating layer appears between the buried insulating layer and the sidewall of the trench, so that a great margin can be ensured for the occurrence of the depression in the removing step. Alternatively, the two layers may be of the same material and, in this case, the entire buried insulating layer can be of a single material so that parts of the buried insulating layer can be uniform in thermal expansion. Therefore, stress is unlikely to occur that is due to difference in thermal expansion between the parts of the buried insulating layer.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view schematically showing a structure of a semiconductor device having a trench isolation according to a first embodiment of the present invention.

FIG. 2 is a cross-sectional view schematically showing a structure of a semiconductor device having a trench isolation according to a third embodiment of the present invention.

FIGS. 3-11 are schematic cross-sectional views successively showing steps of a manufacturing method of a semiconductor device having a trench isolation according to a fourth embodiment of the present invention.

FIG. 12 is a schematic cross-sectional view showing a method of manufacturing a semiconductor device having a trench isolation according to a fifth embodiment of the present invention.

FIGS. 13-15 are schematic cross-sectional views successively showing steps of a manufacturing method of a semiconductor device according to a sixth embodiment of the present invention.

FIG. 16 is a schematic cross-sectional view showing a method of manufacturing a semiconductor device having a trench isolation according to a seventh embodiment of the present invention.

FIGS. 17-21 are schematic cross-sectional views successively showing steps of a manufacturing method of a semiconductor device according to an eighth embodiment of the present invention.

FIGS. 22 and 23 are schematic cross-sectional views successively showing steps of a method of manufacturing a semiconductor device having a trench isolation according to a ninth embodiment of the present invention.

FIGS. 24 and 25 are schematic cross-sectional views successively showing steps of a method of manufacturing a semiconductor device having a trench isolation according to a tenth embodiment of the present invention.

FIGS. 26 and 27 are schematic cross-sectional views successively showing steps of a method of manufacturing a semiconductor device having a trench isolation according to an eleventh embodiment of the present invention.

FIG. 28 is a schematic plan view showing the trench isolation of the first embodiment shown in FIG. 1 that electrically isolates a MOS transistor from other elements.

FIG. 29 is a schematic cross-sectional view along line XXIX-XXIX in FIG. 28.

FIG. 30 is a schematic cross-sectional view along line XXX-XXX in FIG. 28.

FIG. 31 is a schematic plan view showing the trench isolation of the first embodiment shown in FIG. 1 that electrically isolates a flash memory from other elements.

FIG. 32 is a schematic cross-sectional view along line XXXI-XXXII in FIG. 31.

FIG. 33 is a cross-sectional view of the first to the eleventh embodiments showing the dimension of each part of the trench isolation.

### DESCRIPTION OF THE PREFERRED EMBODIMENTS

Embodiments of the present invention are hereinafter described in conjunction with the drawings.

First Embodiment

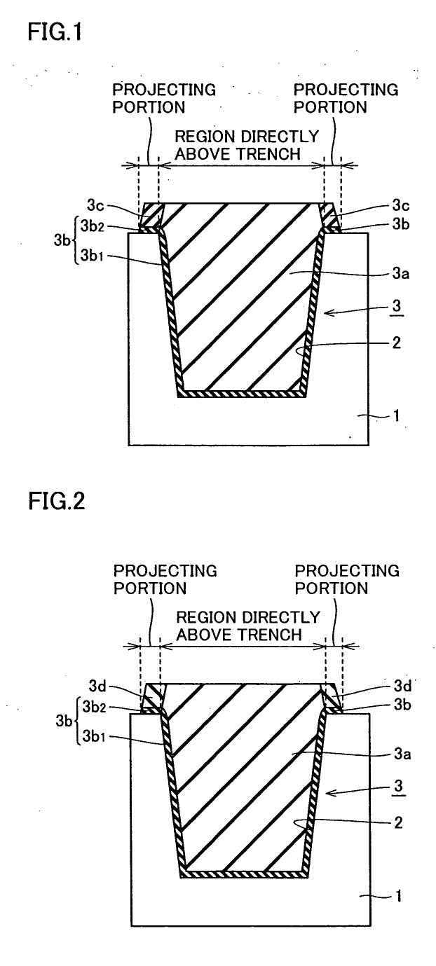

Referring to FIG. 1, a semiconductor device according to this embodiment has a trench isolation for electrically isolating a semiconductor element from other semiconductor elements. The trench isolation includes a trench 2 formed in the surface of a semiconductor substrate 1 of silicon for example to serve for the trench isolation, and a buried insulating layer 3 filling the inside of this trench 2 and thus is buried therein. Buried insulating layer 3 fills the inside of trench 2 and protrudes from the surface of semiconductor substrate 1. The protruded part has a projecting portion which is located on the surface of semiconductor substrate 1 and projects in the outward direction (direction parallel to the surface of the semiconductor substrate) from a region located directly above trench 2. The projecting portion has a structure formed of at least two stacked insulating layers. The whole top surface of buried insulating layer 3 is located above the surface of semiconductor substrate 1.

More specifically, buried insulating layer 3 has insulating layers 3a, 3b and 3c. Insulating layer 3b has insulating layers 3b₁ and 3b₂. Insulating layer 3b₁ is formed along the inner surface (the sidewall and the bottom surface) of trench 2. Insulating layer 3a is formed to fill the inside of trench 2 and protrude from the surface of semiconductor substrate 1. Insulating layer 3a has a substantially flat top surface. Insulating layers 3b₂ and 3c are formed to cover the sidewall of the protruding part of insulating layer 3a and accordingly constitute the projecting portion. Insulating layer 3b₂ abuts on the surface of semiconductor substrate 1 and insulating layer 3c is formed on insulating layer 3b₂.

According to this embodiment, buried insulating layer 3 has the projecting portion which is located on the surface of semiconductor substrate 1 and projects outward from the region directly above trench 2, so that a depression of buried insulating layer 3 that could appear between buried insulating layer 3 and the sidewall of trench 2 is prevented from occurring. Thus, occurrence of the reverse narrow-channel effect and deterioration in reliability of the gate insulating layer, due to occurrence of the depression, can be prevented.

Moreover, as the projecting portion has the structure formed of at least two stacked insulating layers 3b₂ and 3c, these two layers 3b₂ and 3c may be of different materials respectively or the same material. Two layers 3b₂ and 3c may be of different materials respectively in such a manner that the material of the upper insulating layer 3c is hard to remove in the step of removing the lower insulating layer 3b₂. In this case, in the step of removing the lower insulating layer 3b₂, it hardly occurs that a depression of buried insulating layer 3 appears between buried insulating layer 3 and the sidewall of trench 2, so that a large margin can be ensured for the occurrence of the depression in the removing step. Alternatively, these two layers 3b₂ and 3c may be of the same material and, in this case, buried insulating layer 3 can entirely be of a single material so that parts of buried insulating layer 3 can be uniform in thermal expansion. Therefore, stress is unlikely to occur that is due to differences in thermal expansion between the parts of buried insulating layer 3.

Further, the entire top surface of insulating layer 3a is substantially flat, which makes it easy to pattern a gate electrode of, for example, a MOS transistor formed on the insulating layer.

Second Embodiment

Referring to FIG. 1, a semiconductor device of this embodiment has a projecting portion formed of insulating layers 3b₂ and 3c that are different silicon oxide films. Insulating layer 3b₂ is made of a silicon oxide film formed by thermal oxidation (hereinafter referred to as thermal oxide film) while insulating layer 3c is made of a silicon oxide film formed by a method different from the thermal oxidation, for example, a silicon oxide film formed by HDP (High Density Plasma, the film hereinafter referred to as HDP oxide film), or a silicon oxide film formed by TEOS (Tetra-Ethyl-Ortho-Silicate, the film hereinafter referred to as TEOS oxide film). Therefore, insulating layer 3b₂ and insulating layer 3c are different in quality.

Insulating layer 3a is made of, for example, an HDP oxide film and insulating layer 3b₁ is made of, for example, a thermal oxide film.

Although insulating layer 3a and insulating layer 3c may be formed of different layers, they may be formed of the same layer. In addition, insulating layer 3b₁ and insulating layer 3b₂ may be formed of different layers while they may be formed of the same layer.

It is noted that details of the structure of this embodiment except for the above described ones are substantially the same as corresponding ones of the first embodiment, like components are thus denoted by like reference characters and description thereof is not repeated here.

According to this embodiment, insulating layer 3b₂ and insulating layer 3c are both made of the silicon oxide films so as to allow the whole of buried insulating layer 3 to be formed of the silicon oxide films. If different materials are used to form respective parts of buried insulating layer 3, stress arises due to a difference in thermal expansion of the materials, for example. According to this embodiment, however, there is no influence of the stress due to such a difference in thermal expansion, since the whole of buried insulating layer 3 can be formed of the silicon oxide films.

Moreover, insulating layer 3b₂ formed directly on the surface of semiconductor substrate 1 is a thermal oxide film having less impurities as compared with an oxide film formed by CVD (Chemical Vapor Deposition) for example, which is unlikely to adversely influence characteristics of a semiconductor device formed on the semiconductor substrate.

Third Embodiment

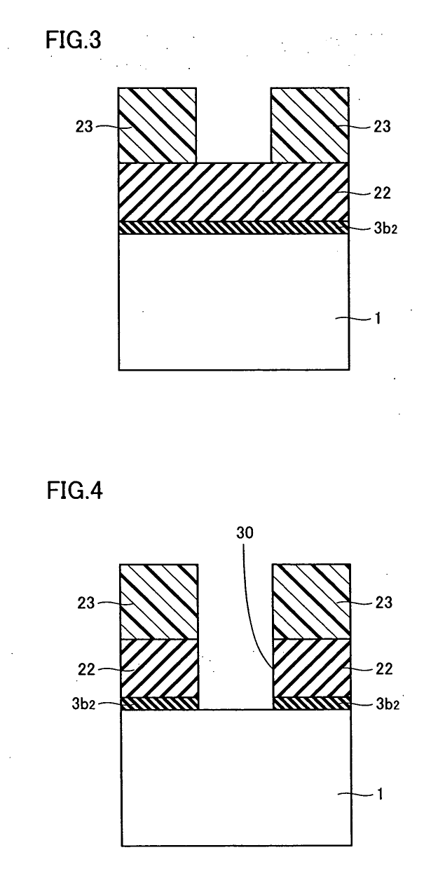

Referring to FIG. 2, a structure of this embodiment differs from that of the second embodiment in that insulating layers 3b₂ and 3d forming the projecting portion of buried insulating layer 3 are made of different materials. Insulating layer 3b₂ is made of a thermal oxide film while insulating layer 3d is made of a silicon nitride film.

Insulating layer 3a is made of a silicon oxide film and thus insulating layer 3a and insulating layer 3d are made of different materials.

It is noted that details of the structure of this embodiment except for the above described ones are substantially the same as corresponding ones of the second embodiment, like components are thus denoted by like reference characters and description thereof is not repeated here.

According to this embodiment, insulating layer 3d is made of the silicon nitride film which is hardly etched away in the step of wet-etching insulating layer 3b₂ by using an HF (hydrofluoric acid)—based solution. Therefore, it is more unlikely, compared with the second embodiment, that a depression of buried insulating layer 3 occurs between of buried insulating layer 3 and the sidewall of trench 2. In this way, a large margin for the occurrence of the depression in the etching step as mentioned above can be ensured.

Moreover, insulating layer 3b₂ formed directly on the surface of semiconductor substrate 1 is a thermal oxide film having less impurities as compared with an oxide film formed by CVD for example, which is unlikely to adversely influence characteristics of a semiconductor device formed on the semiconductor substrate.

Fourth Embodiment

This embodiment relates to a manufacturing method for the second embodiment.

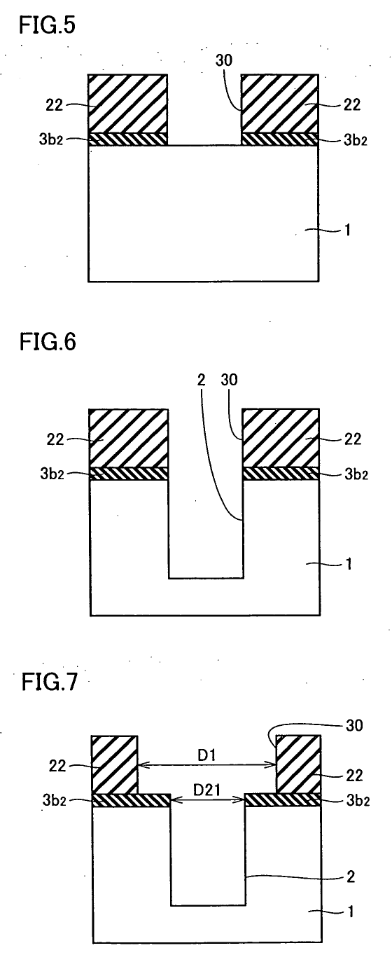

Referring to FIG. 3, on a surface of semiconductor substrate 1, a thermal oxide film 3b₂ and a silicon nitride film 22 are successively deposited. A photoresist 23 is applied to silicon nitride film 22 and is patterned by the usual photolithography technique to form resist pattern 23.

Referring to FIG. 4, resist pattern 23 is used as a mask to anisotropically etch silicon nitride film 22 and thermal oxide film 3b₂. Resist pattern 23 is thus transferred to silicon nitride film 22 and thermal oxide film 3b₂ to make a hole 30 which partially exposes the surface of semiconductor substrate 1. Resist pattern 23 is thereafter removed by, for example, ashing.

Referring to FIG. 5, the removal of resist patter 23 then exposes the top surface of silicon nitride film 22.

Referring to FIG. 6, silicon nitride film 22 is used as a mask to anisotropically etch semiconductor substrate 1. In this way, trench 2 for the trench isolation is formed in the surface of semiconductor substrate 1.

Referring to FIG. 7, immediately after trench 2 is formed, silicon nitride film 22 is wet-etched by means of a chemical solution of hot phosphoric acid for example that dissolves the silicon nitride film. Accordingly, the thickness of silicon nitride film 22 decreases and the dimension of the opening D1 of hole 30 in silicon nitride film 22 is greater than the dimension of opening D21 of hole 30 in thermal oxide film 3b₂.

Referring to FIG. 8, the inner surface of trench 2 is oxidized by thermal oxidation to form thermal oxide film 3b₁ along the inner surface of trench 2. This thermal oxide film 3b₁ extending along the inner surface of trench 2 and thermal oxide film 3b₂ formed on the top surface of semiconductor substrate 1 form oxide film 3b.

Referring to FIG. 9, silicon oxide film 3a of, for example, HDP oxide film is deposited to fill trench 2 and hole 30 and to cover silicon nitride film 22.

Referring to FIG. 10, silicon oxide film 3a is polished away by CMP until the top surface of silicon nitride film 22 is exposed. Accordingly, silicon oxide film 3a is left within trench 2 and hole 30 and respective top surfaces of silicon nitride film 22 and silicon oxide film 3a are planarized. Silicon nitride film 22 and thermal oxide film 3b on an active region are thereafter removed.

Referring to FIG. 11, the removal of silicon nitride film 22 and thermal oxide film 3b leaves buried insulating layer 3 formed of thermal oxide film 3b and silicon oxide film 3a and thereby the trench isolation of this embodiment is completed.

In this embodiment, silicon oxide film 3a of buried insulating layer 3 corresponds to a combination of insulating layers 3a and 3c of buried insulating layer 3 shown in FIG. 1.

According to this embodiment, in the step shown in FIG. 10, silicon oxide film 3a is formed in advance to project outward (in the lateral direction as seen in FIG. 10), to a considerable degree, from the region directly above trench 2. Therefore, although silicon oxide film 3a is removed to a certain degree in the step of removing thermal oxide film 3b shown in FIG. 11, the projecting portion of silicon oxide film 3a is left. Silicon oxide film 3a can thus be prevented from being laterally etched away to the extent that the projecting portion of silicon oxide film 3a disappears. Therefore, a depression of buried insulating layer 3 that could appear between the buried insulating layer and the sidewall of trench 2 can also be prevented. In this way, occurrence of the reverse narrow-channel effect as well as deterioration in reliability of the gate insulating layer due to the depression can be prevented.

Moreover, according to this embodiment, only the wet-etching step for silicon nitride film 22 shown in FIG. 7 is added as compared with the conventional manufacturing process so that an increase of the number of steps can also be avoided.

Fifth Embodiment

This embodiment relates to a manufacturing method for the second embodiment.

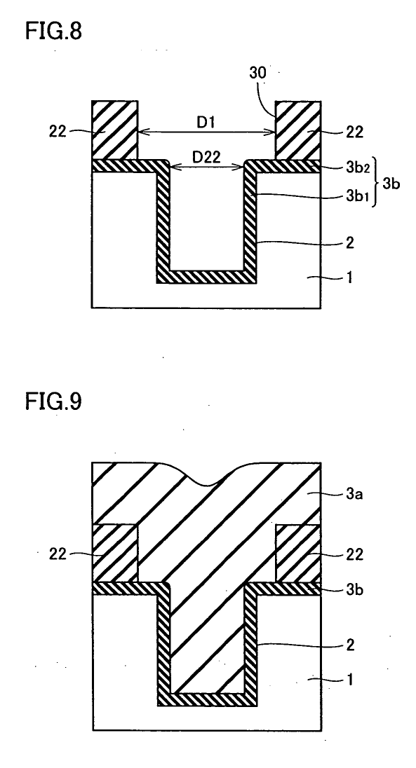

Initial steps of the manufacturing method of this embodiment are similar to those of the fourth embodiment shown respectively in FIGS. 3-6. After this, referring to FIG. 12, the inner surface of trench 2 is oxidized by the thermal oxidation method to form thermal oxide film 3b₁ along the inner surface of trench 2. Oxide film 3b formed of thermal oxide film 3b₁ extending along the inner surface of trench 2 and thermal oxide film 3b₂ formed on the top surface of semiconductor substrate 1 is thus completed.

Referring to FIG. 8, immediately after the above-described thermal oxide film 3b₁ is formed, silicon nitride film 22 is wet-etched by a chemical solution of hot phosphoric acid for example that dissolves the silicon nitride film. Accordingly, the thickness of silicon nitride film 22 decreases, and the dimension D1 of the opening of silicon nitride film 22 in hole 30 is greater than the dimension D22 of the opening of oxide film 3b in hole 30.

After this, according the manufacturing method of this embodiment, similar steps to those of the fourth embodiment shown respectively in FIGS. 9-11 are carried out to complete a trench isolation of this embodiment.

According to this embodiment, an effect similar that of the fourth embodiment can be achieved. Moreover, the wet etching step for silicon nitride film 22 is done in the state where the inner surface of trench 2 is covered with oxide film 3b₁ in the steps shown in FIGS. 7 and 8, and thus it is possible to prevent the etching solution from being brought into direct contact with the surface of semiconductor substrate 1.

Sixth Embodiment

This embodiment relates to a manufacturing method for the second embodiment.

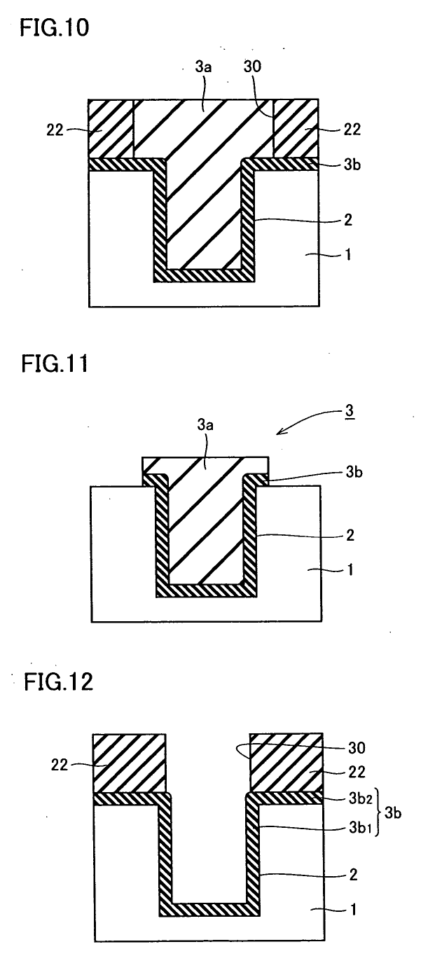

Referring to FIG. 13, the manufacturing method of this embodiment chiefly differs from that of the fourth embodiment in that a film 25 containing silicon is formed between thermal oxide film 3b₂ and silicon nitride film 22. A polycrystalline silicon film for example is formed as this film 25 containing silicon. After thermal oxide film 3b₂, polycrystalline silicon film 25 and silicon nitride film 22 are formed, hole 30 and trench 2 are made as done in the fourth embodiment.

Referring to FIG. 14, as done in the fourth embodiment, silicon nitride film 22 is wet-etched by a chemical solution of hot phosphoric acid or the like that dissolves the silicon nitride film. Accordingly, the thickness of silicon nitride film 22 decreases, and the dimension D1 of the opening of silicon nitride film 22 in hole 30 is greater than the dimension D23 of polycrystalline silicon film 25 and thermal oxide film 3b₂ that are located in hole 30.

Referring to FIG. 15, the inner surface of trench 2 and a part of polycrystalline silicon film 25 are oxidized by the thermal oxidization method. Thermal oxide film 3b₁ along the inner surface of trench 2 as well as thermal oxide film 3b₃ which is the oxidized part of polycrystalline silicon film 25 are formed. These thermal oxide films 3b₁, 3b₂ and 3b₃ thus form oxide film 3b.

According to the manufacturing method of this embodiment, through the following steps that are similar to those of the fourth embodiment shown respectively in FIGS. 9-11, a trench isolation of this embodiment is completed.

According to this embodiment, an effect similar to that of the fourth embodiment can be achieved. Moreover, silicon-containing film 25 is formed as a buffer layer. Then, the phase state and the concentration of impurities, for example, of this silicon-containing film 25 may be changed to facilitate control of the manner in which silicon-containing film 25 is oxidized in the thermal oxidation step. Consequently, the occurrence of the depression of buried insulating layer 3, that could appear between buried insulating layer 3 and the sidewall of trench 2, is more easily prevented.

Seventh Embodiment

This embodiment relates to a manufacturing method for the second embodiment.

The manufacturing method of this embodiment chiefly differs from that of the fifth embodiment in that a film 25 containing silicon is formed between thermal oxide film 3b₂ and silicon nitride film 22.

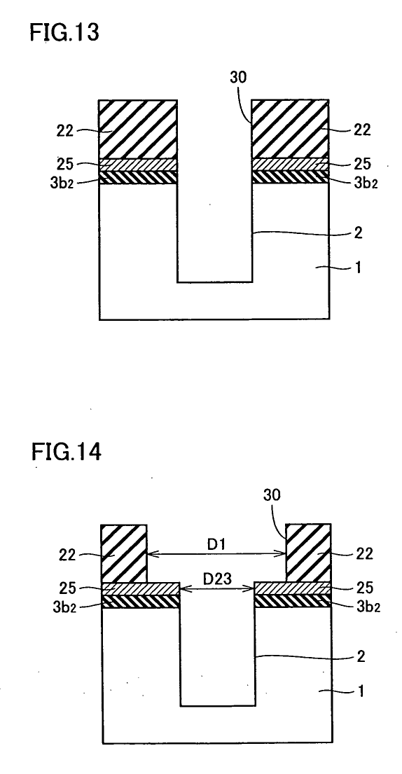

According to this embodiment, a step similar to that of the sixth embodiment shown in FIG. 13 is carried out. Referring to FIG. 16, the inner surface of trench 2 and a part of polycrystalline silicon film 25 are thereafter oxidized by the thermal oxidation method. Accordingly, thermal oxide film 3b₁ along the inner surface of trench 2 as well as thermal oxide film 3b₃ which is the oxidized part of polycrystalline silicon film 25 are formed. These thermal oxide films 3b₁, 3b₂ and 3b₃ form oxide film 3b.

Referring to FIG. 15, immediately after thermal oxide films 3b₁ and 3b₃ are formed, silicon nitride film 22 is wet-etched by a chemical solution of hot phosphoric acid or the like that dissolves the silicon nitride film. Accordingly, the thickness of silicon nitride film 22 decreases, and the dimension D1 of the opening of silicon nitride film 22 in hole 30 is greater than the dimension D24 of oxide film 3b located in hole 30.

According to the manufacturing method of this embodiment, through the following steps that are similar to those of the fourth embodiment shown respectively in FIGS. 9-11, a trench isolation of this embodiment is completed.

According to this embodiment, an effect similar to that of the fifth embodiment can be achieved. Moreover silicon-containing film 25 is formed as a buffer layer. Then, the phase state and the concentration of impurities, for example, of this silicon-containing film 25 may be changed to facilitate control of the manner in which silicon-containing film 25 is oxidized in the thermal oxidation step. Consequently, the occurrence of the depression of buried insulating layer 3, that could appear between buried insulating layer 3 and the sidewall of trench 2, is more easily prevented.

Eighth Embodiment

This embodiment relates to a manufacturing method for the second embodiment.

The manufacturing method of this embodiment follows the steps respectively shown in FIGS. 3-6 and then the step shown in FIG. 12.

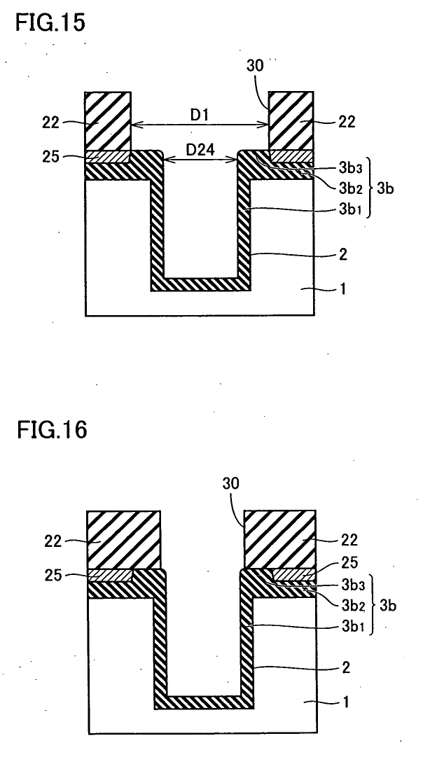

Referring to FIG. 17, silicon oxide film 3a formed of an HDP oxide film, for example, is thereafter formed to fill trench 2 and hole 30 and cover silicon nitride film 22.

Referring to FIG. 18, silicon oxide film 3a is polished away by CMP until the top surface of silicon nitride film 22 is exposed. Accordingly, silicon oxide film 3a is left within trench 2 and hole 30, and respective top surfaces of silicon nitride film 22 and silicon oxide film 3a are planarized. After this, silicon nitride film 22 and thermal oxide film 3b₂ on an active region are removed.

Referring to FIG. 19, the removal of silicon nitride film 22 and thermal oxide film 3b₂ temporarily exposes the surface of semiconductor substrate 1, while thermal oxide film 3b₁ and silicon oxide film 3a are left in trench 2. After this, the exposed surface of semiconductor substrate 1 is oxidized by the thermal oxidation method to form thermal oxide film 3b₂.

Referring to FIG. 20, TEOS oxide film 3c is formed to cover silicon oxide film 3a and thermal oxide film 3b₂. After this, the entire surface is anisotropically etched (etched back) until the surface of semiconductor substrate 1 is partially exposed.

Referring to FIG. 21, the etch-back process leaves thermal oxide film 3b₂ and TEOS oxide film 3c only on the lateral side of a part of silicon oxide film 3a that protrudes from the surface of semiconductor substrate 1. In this way, buried insulating layer 3 formed of silicon oxide film 3a, thermal oxide films 3b₁ and 3b₂ and TEOS oxide film 3c is produced. Of these oxide films, thermal oxide film 3b₂ and TEOS oxide film 3c form a projecting portion. A trench isolation of this embodiment is accordingly completed.

According to this embodiment, TEOS oxide film 3c is formed on the entire surface that is then etched back, so that a depression of the silicon oxide film that could appear between silicon oxide film 3a and the sidewall of trench 2 can be filled and the projecting portion of buried insulating layer 3 can be formed. Thus, it is achieved to prevent occurrence of the reverse narrow channel effect as well as deterioration in reliability of the gate insulating layer that are caused due to the presence of the depression.

Ninth Embodiment

This embodiment relates to a manufacturing method for the second embodiment.

The manufacturing method of this embodiment initially follows the steps similar to those of the eighth embodiment to the step shown in FIG. 20. After this, the entire surface of TEOS oxide film 3c is anisotropically etched to the degree that the surface of the semiconductor substrate 1 is not exposed.

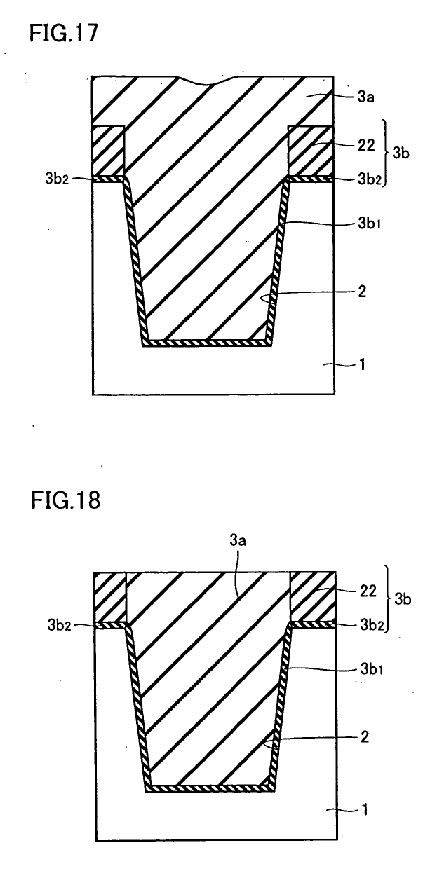

Referring to FIG. 22, the etch-back step leaves thermal oxide film 3b₂ and a part of TEOS oxide film 3c on the surface of semiconductor substrate 1. The silicon oxide film is thereafter wet-etched until a part of the surface of semiconductor substrate 1 is exposed.

Referring to FIG. 23, the wet-etching step leaves thermal oxide film 3b₂ and a TEOS oxide film 3c only on the lateral side of a part of silicon oxide film 3a that protrudes from the surface of semiconductor substrate 1. Accordingly, buried insulating layer 3 which is formed of silicon oxide film 3a, thermal oxide films 3b₁ and 3b₂ and TEOS oxide film 3c is completed. Of these oxide films, thermal oxide film 3b₂ and TEOS oxide film 3c form a projecting portion. A trench isolation of this embodiment is thus completed.

According to this embodiment, a similar effect to that of the eighth embodiment can be achieved. Moreover, a plasma-caused damage on the surface of semiconductor substrate 1 can be avoided since semiconductor substrate 1 does not undergo the dry-etching in the etch-back step.

Tenth Embodiment

This embodiment relates to a manufacturing method for the third embodiment.

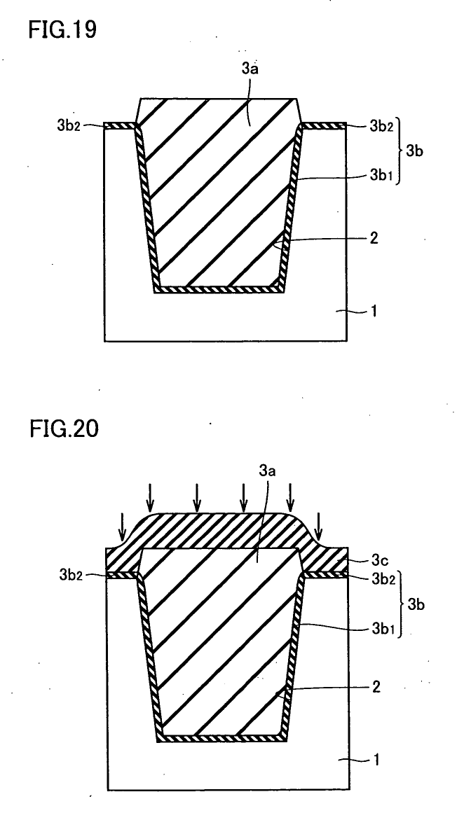

The manufacturing method of this embodiment follows the steps similar to those of the eighth embodiment to the step shown in FIG. 19. Referring to FIG. 24, silicon nitride film 3d is thereafter formed to cover silicon oxide film 3a and thermal oxide film 3b₂. Then, the entire surface of silicon nitride film 3d is anisotropically etched (etched back) until a part of the surface of semiconductor substrate 1 is exposed.

Referring to FIG. 25, the etch-back step leaves thermal oxide film 3b₂ and silicon nitride film 3d only on the lateral side of a part of silicon oxide film 3a that protrudes from the surface of semiconductor substrate 1. Accordingly, buried insulating layer 3 formed of silicon oxide film 3a, thermal oxide films 3b₁ and 3b₂ and silicon nitride film 3d is produced. Thermal oxide film 3b₂ and silicon nitride film 3d form a projecting portion of buried insulating layer 3. A trench isolation of this embodiment is thus completed.

According to this embodiment, silicon nitride film 3d is formed on the entire surface that is then etched back, so that a depression of the silicon oxide film that could appear between silicon oxide film 3a and the sidewall of trench 2 can be filled and the projecting portion of buried insulating layer 3 can be formed. Thus, it is achieved to prevent occurrence of the reverse narrow channel effect as well as deterioration in reliability of the gate insulating layer that are caused due to the presence of the depression.

Moreover, since insulating layer 3b₂ formed directly on the surface of semiconductor substrate 1 is the thermal oxide film which is smaller in the number of impurities as compared with an oxide film formed by the CVD or the like, it hardly occurs that characteristics of a semiconductor element formed on the semiconductor substrate are adversely affected.

Eleventh Embodiment

This embodiment relates to a manufacturing method for the third embodiment.

The manufacturing method of this embodiment follows the steps similar to those of the tenth embodiment to the step shown in FIG. 24. After this, the entire surface of silicon nitride film 3d is anisotropically etched (etched back) until a part of thermal oxide film 3b₂ is exposed.

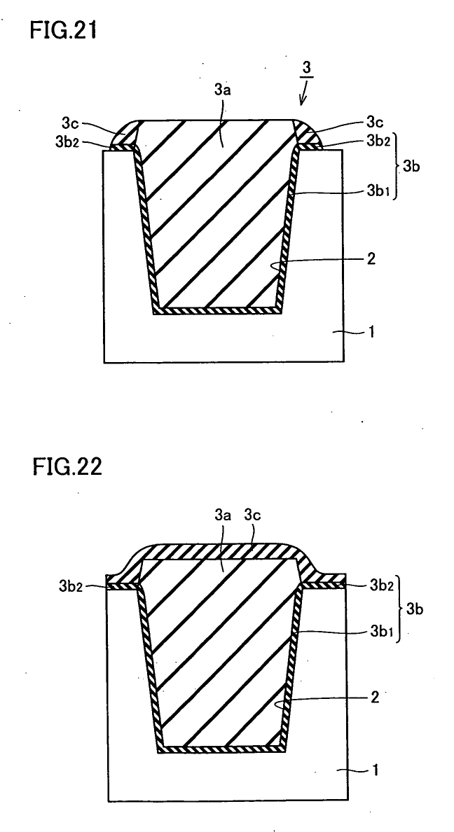

Referring to FIG. 26, the etch-back step leaves silicon nitride film 3d only on the lateral side of a part of silicon oxide film 3a that protrudes from the surface of semiconductor substrate 1. After this, the silicon oxide film is wet-etched by an HF (hydrofluoric acid)—based solution until a part of the surface of semiconductor substrate 1 is exposed.

Referring to FIG. 27, the wet-etching step leaves thermal oxide film 3b₂ only on the lateral side of the part of silicon oxide film 3a that protrudes from the surface of semiconductor substrate 1 and under silicon nitride film 3d. Accordingly, buried insulating layer 3 formed of silicon oxide film 3a, thermal oxide films 3b₁ and 3b₂ and silicon nitride film 3d is produced. Thermal oxide film 3b₂ and silicon nitride film 3d form a projecting portion of buried insulating layer 3. A trench isolation of this embodiment is thus completed.

According to this embodiment, a similar effect to that of the tenth embodiment can be achieved. Moreover, since semiconductor substrate 1 is not subjected to the dry-etching in the etch-back step, a plasma-caused damage on the surface of semiconductor substrate 1 can be avoided.

In addition, the silicon nitride film is hardly etched away in the wet-etching step for thermal oxide film 3b₁ by means the of HF (hydrofluoric acid)—based solution. Then, it hardly occurs that a depression of buried insulating layer 3 appears between buried insulating layer 3 and the sidewall of trench 2, as compared with the tenth embodiment, so that a great margin can be ensured for occurrence of the depression in the etching step.

It is noted that respective trench isolations of the first to eleventh embodiments are used for electrically isolating a semiconductor element from other semiconductor elements. A description is now given below of the way in which the trench isolation of the first embodiment shown in FIG. 1 electrically isolates a MOS transistor, for example, from other elements.

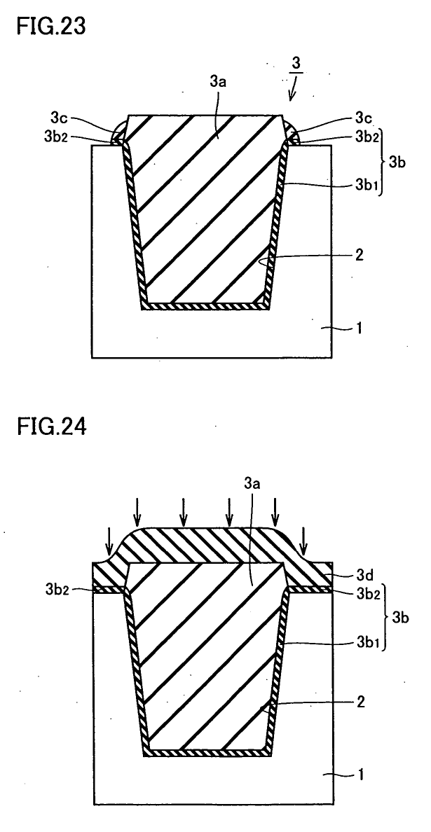

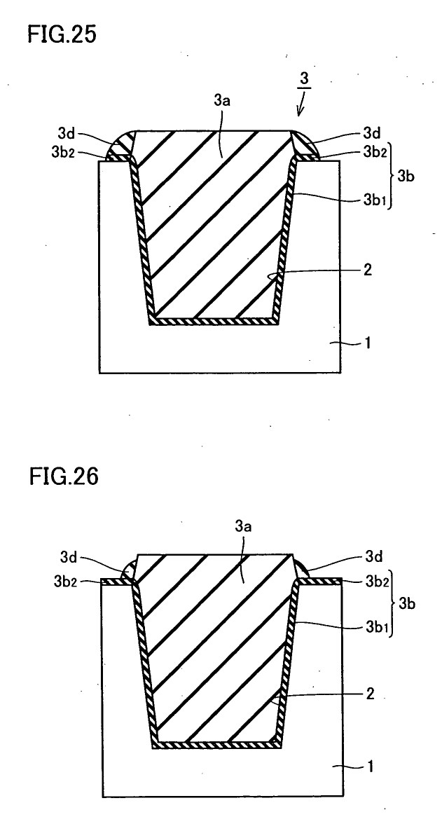

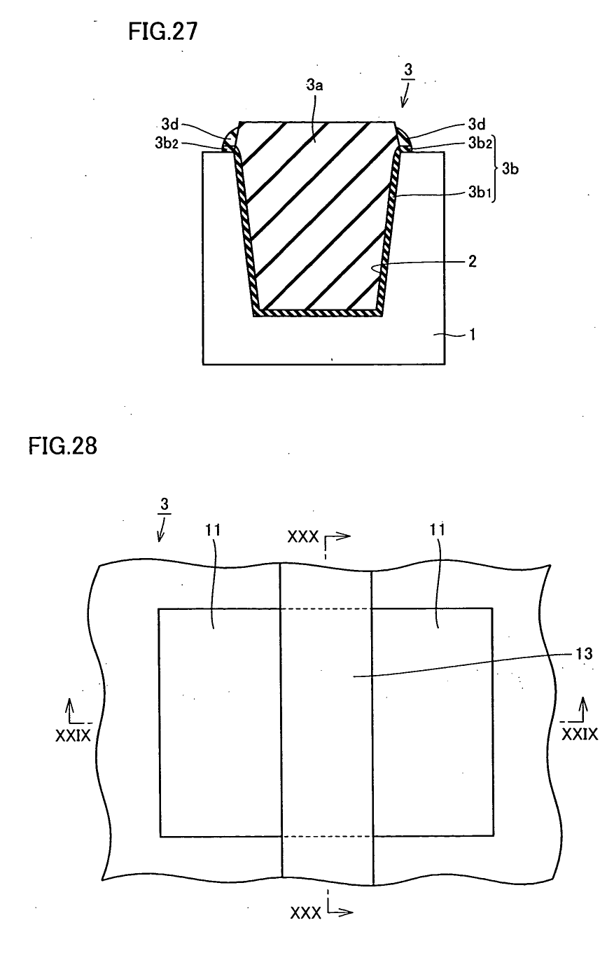

Referring to FIGS. 28-30, a trench isolation formed of trench 2 which is made in the surface of semiconductor substrate 1 and buried insulating layer 3 which fills the inside of trench 2 is formed to surround an active region. A MOS transistor 10 is formed in this active region.

MOS transistor 10 has a pair of source/drain regions 11, a gate oxide film 12 and a gate electrode 13. The paired source/drain regions 11 are formed in the surface of the active region and spaced from each other. Gate electrode 13 is formed on a region sandwiched between paired source/drain regions 11 with gate oxide film 12 therebetween.

Gate electrode 13 extends in one direction across the active region, for example. In this case, gate electrode 13 extends over projecting portions 3b and 3c of buried insulating layer 3. If an interlayer insulating layer (not shown) is formed to cover MOS transistor 10, this interlayer insulating layer is also formed on projecting portions 3b and 3c of buried insulating layer 3. In other words, on projecting portions 3b and 3c of buried insulating layer 3, a conductive layer and an insulating layer are formed at upper levels.

The trench isolation thus surrounds the region where MOS transistor 10 is formed so as to electrically isolate MOS transistor 10 from other semiconductor elements.

A description is now given below of the way in which the trench isolation of the first embodiment shown in FIG. 1 electrically isolates a flash memory, for example, from other elements.

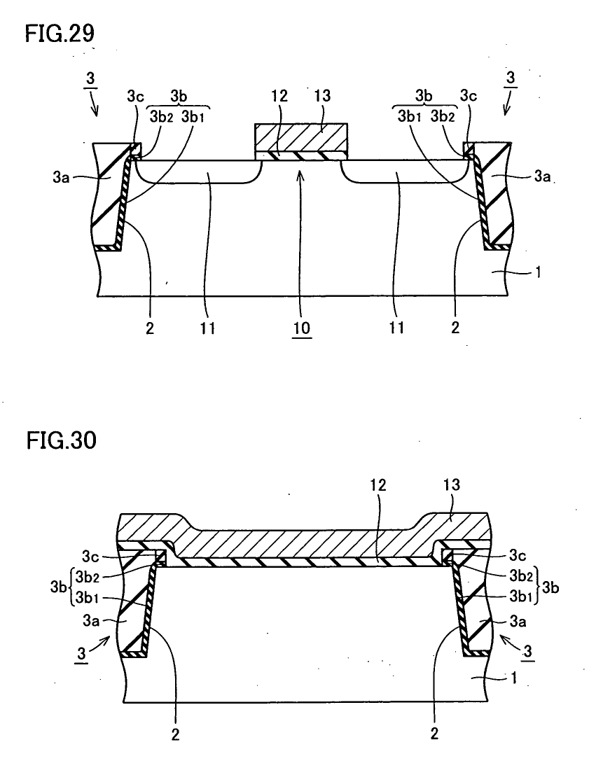

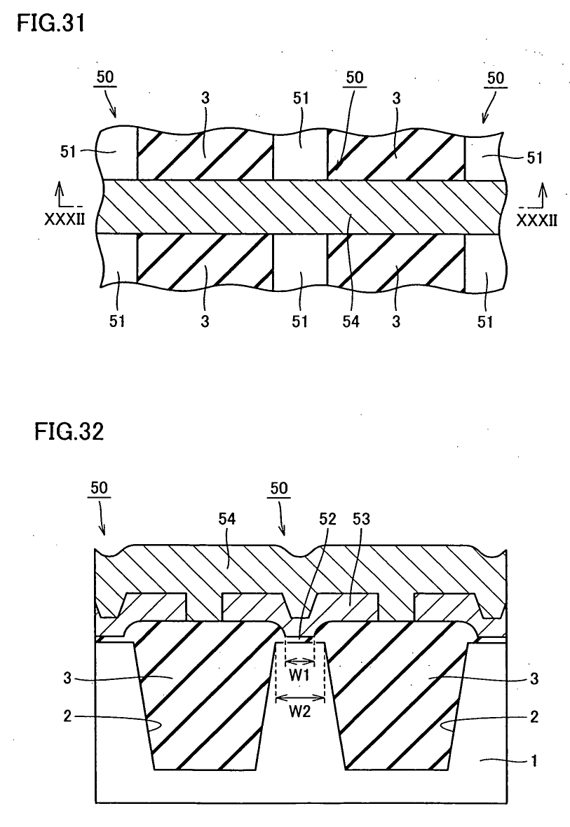

Referring to FIGS. 31 and 32, a trench isolation formed of trench 2 made in the surface of semiconductor substrate 1 and buried insulating layer 3 which fills the inside of trench 2 is formed to surround an active region. In this active region, a flash memory 50 is formed.

Flash memory 50 has a pair of source/drain regions 51, a gate insulating film 52, a floating gate electrode 53, and a control gate electrode 54. Although an insulating film is formed between floating gate electrode 53 and control gate electrode 54 for electrically insulating floating gate electrode 53 and control gate electrode 54, this insulating film is not shown for convenience of description.

Paired source/drain regions 51 are formed in the surface of the active region and spaced apart. On a region sandwiched between paired source/drain regions 51, floating gate electrode 53 is formed with gate insulating film 52 therebetween. Control gate electrode 54 extends over floating gate electrode 53 with the insulating film (not shown) therebetween.

Control gate electrode 54 extends in one direction across the active region for example. In this case, control gate electrode 54 extends over the projecting portion of buried insulating layer 3. If an interlayer insulating layer (not shown) is formed to cover flash memory 50, this interlayer insulating layer is also formed over the projecting portion of buried insulating layer 3. In other words, on the projecting portion of buried insulating layer 3, a conductive layer and an insulating layer are formed at upper levels.

The trench isolation thus surrounds the region where flash memory 50 is formed so as to electrically isolate flash memory 50 from other semiconductor elements.

By electrically isolating flash memory 50 from other elements by the trench isolation of this embodiment as described above, the width W1 of the gate insulating film between buried insulating layers 3 can be made smaller than the width W2 of the active region between trenches 2 because of the presence of the projecting portion of buried insulating layer 3. Accordingly, the area of gate insulating film 52 facing the surface of semiconductor substrate 1 can be made smaller. The coupling capacitance thus increases (a relative difference in potential between floating gate electrode 53 and semiconductor substrate 1 increases) to improve the efficiency in erasure and writing of data of flash memory 50.

Although the MOS transistor and the flash memory have been described, the present invention is not limited to them and is applicable to electrical isolation of other semiconductor elements.

Each part of the trench isolation in the first to eleventh embodiments has its dimension as described below.

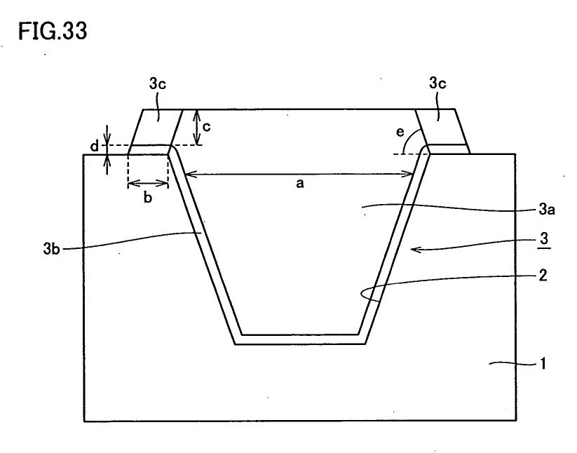

Referring to FIG. 33, the width “a” of insulating layer 3a in trench 2 is, for example, at least 0.10 μm and at most 0.30 μm, and this width is determined depending on the limit at which the insulating layer can fill the whole of the trench. The dimension “b” of the projecting portion of buried insulating layer 3 is, for example, at least 20 nm and at most 50 nm, and this dimension is determined by the total amount etched after the projecting portion is formed. The thickness “c” of insulating layer 3c of the projecting portion is, for example, at least 20 nm and at most 50 nm, and this thickness is determined by the total amount etched after the projecting portion is formed. The thickness “d” of insulating layer 3b of the projecting portion is, for example, at least 3 nm and at most 15 nm. Regarding this thickness “d,” a required thickness varies depending on the etch selectivity since insulating layer 3b is to be covered with an oxide film.

It is preferable that the sum of the thickness “c” and the thickness “1d” (“c+d”, i.e., the total thickness of the projecting portion) is, for example, at least 23 nm and at most 75 nm. If the dimension “c+d” is smaller than 23 nm, it could occur that insulating layer 3c is not formed on semiconductor substrate 1 due to variations in manufacture. If the dimension “c+d” is greater than 75 nm, there is a great difference between the level of semiconductor substrate 1 and buried insulating layer 3, which makes it difficult to pattern a gate electrode formed on buried insulating layer 3.

The angle “e” formed between the sidewall of the part of insulating layer 3a that protrudes from semiconductor substrate 1 and the surface of semiconductor substrate 1 may be, for example, at most 1200 and preferably at most 90°. This angle between the sidewall of insulating layer 3a and the surface of semiconductor substrate 1 may be any unless an extremely reverse-tapered shape is formed by the angle which causes a thin film not to be formed by CVD on the sidewall of insulating layer 3a.

It is noted that FIG. 33 shows no hatching for clearly showing the dimensions.

The dimension of each part is one preferable dimension which does not limit the present invention to the particular dimension.

It has been described with regard to the first to eleventh embodiments that the two layers that are components of the projecting portion of buried insulating layer 3 are silicon oxide films or a combination of a silicon oxide film and a silicon nitride film. Other materials, however, may be employed for these components. In addition, the number of layers of the projecting portion is not limited to two, and the projecting portion may be formed of three or more layers. Further, insulating layer 3a of the fourth to seventh embodiments may be a silicon nitride film.

Although the present invention has been described and illustrated in detail, it is dearly understood that the same is by way of illustration and example only and is not to be taken by way of limitation, the spirit and scope of the present invention being limited only by the terms of the appended claims.

What is claimed is:

1. A semiconductor device having a trench isolation for electrically isolating a semiconductor element from other semiconductor elements, comprising:
a semiconductor substrate having a trench for said trench isolation that is located in a main surface of said semiconductor substrate; and
a buried insulating layer filling the inside of said trench and having its top surface entirely located above the main surface of said semiconductor substrate;
a part of said buried insulating layer that protrudes from the main surface of said semiconductor substrate having a projecting portion which is located on the main surface of said semiconductor substrate and projects outward from a region directly above said trench, and
said projecting portion having a structure formed of at least two stacked insulating layers.

2. The semiconductor device having the trench isolation according to claim 1, wherein
said projecting portion has a structure formed of a first oxide film and a second oxide film that are stacked.

3. The semiconductor device having the trench isolation according to claim 1, wherein
said projecting portion has a structure formed of an oxide film- and a nitride film that are stacked.

4. The semiconductor device having the trench isolation according to claim 1, wherein
said projecting portion has a thickness of at least 23 nm and at most 75 nm.

5. The semiconductor device having the trench isolation according to claim 1, further comprising a gate insulating film formed on the main surface of said semiconductor substrate, wherein
said gate insulating film has its width, defined in a cross section of said semiconductor device, between one portion and the other portion of said buried insulating layer, an active region has its width defined in said cross section between one portion and the other portion of said trench, and the width of said gate insulating film is smaller than the width of said active region.
